(19) United States
(12) Patent Application Publication
(10) Pub. No.: US 2007/0132527 A1
(43) Pub. Date: Jun. 14, 2007

(54) Suppression method and structure for reducing a via stub effect of a substrate

(75) Inventor: Yen-Hao Chen, Taipei (TW)

Correspondence Address: FULBRIGHT AND JAWORSKI LLP, 555 S. FLOWER STREET, 41ST FLOOR, LOS ANGELES, CA, 90071, US

(73) Assignee: INVENTEC CORPORATION

(21) Appl. No.: 11/394,695

(22) Filed: Mar. 31, 2006

(30) Foreign Application Priority Data
Dec. 13, 2005 (TW) 94143990

(51) Int. Cl. H03H 7/38

(52) U.S. Cl. 333/33

(57) ABSTRACT

A suppression method for suppressing a via stub effect of a substrate is disclosed. The suppression method is applicable to a substrate having a via, a first conductive line and a second conductive line connected through the via to the first conductive line. The suppression method includes changing a first width of a first conductive segment of the first conductive line connected to the via, and changing a second width of a second conductive segment of the second conductive line connected to the via, so as to change impedances of the first conductive line and the second conductive line to match with a stub impedance of the via, reduce a parasite impedance of the via stub, reach an impedance match at a designed frequency point, and improve an integrity of a signal after traveling from the first conductive line, the via and the second conductive line.

### FIELD OF THE INVENTION

The present invention relates to suppression methods for the via stub effect, and, more particularly, to a suppression method and its structure for the via stub effect of the substrate.

### BACKGROUND OF THE INVENTION

With the demands asked by circuits operating at a high speed for bandwidth keep growing, loss, reflection and crosstalk effects are becoming three of the most important issues in the art. The problem regarding to the signal integrity occurs if a transmission rate is as high as several Gbps, causing some serious problems such as skin effect, dielectric loss, reflection, crosstalk, and inter-symbol interference (ISI).

The substrate is a complex environment comprising by many different elements, and now it has become a challenge for the signal transmission rate up to several Gbps. Every single element on the substrate has its own impedance, and there are more than ten via on the signal path; every via has through and stub, which causes a discontinuous impedance and harmonic zero. In result, characteristics of signals transmitted in such an environment are affected. When a circuit is operating at a very high speed, although the signal channels exist some differences, for example the discontinuous impedance of via, the signal reflection is not very obvious. However, when the circuit is operating at a high speed, with the differences in signal layer (and the via through/stub ratio), length of chamfer and different dielectric materials, which will result in a huge difference between every message channel. It is an enormous challenge for high-speed serial to achieve a high data transmission rate in an environment that message channels have huge differences in character.

Referring to FIG. 1, in a multilayer printed circuit board (PCB) 1, normally via 10 is used to electrical connect the signal conductive line 13 14 from different signal layer. During the fabrication process of the current industries, via is mostly accomplished by a through via method. Therefore, if the signal line being connected is strip line structure (signal line in the inner layer), this will leave an open stub 15 at the whole via. Because the open stub 15 gives a negative affect to the whole signal line's signal quality, which means, this open stub of the via will let the whole circuit's match problems of impedance, such as the variance of capacitance and inductance. Therefore, the open stub needs to be rid of during the fabrication process.

At the present, the method used to eliminate the open stub during the fabrication process of the multilayer PCB 1 is back drill. This method is using a drill to rid of the open stub 15 from beneath bottom to top. But the back drill not only requires the extra cost, but also increases the original via 10 diameters; thereof affects the wiring routing space on the multiplayer PCB. Furthermore, the back drill prolongs the fabrication period of the multilayer PCB 1 and increases the relative cost.

Therefore, to provide a suppression method and structure to reduce the via stub effect of the substrate, to overcome the drawbacks of the conventional technology, has become a problem needs to be resolved.

### SUMMARY OF THE INVENTION

In light of the above drawbacks in the prior art, an objective of the present invention is to provide a suppression method and structure for reducing the via stub effect of the substrate, to increase the signal integrity during transmission.

Another objective of the present invention is to provide a suppression method and structure for reducing the via stub effect of the substrate, to save the extra drilling time and cost.

A further objective of the present invention is to provide a suppression method and structure for reducing the via stub effect of the substrate, to avoid the negative effects such as parasite capacitance on the via open stub under circumstance that not affecting the wiring space on the substrate.

In accordance with the above and other objectives, the present invention provides a suppression method for reducing the via stub effect of the substrate, applying on the substrate which has via and uses electrical connection to connect the first conductive line and the second conductive line. The suppressing method includes changing a first width of a first conductive segment of the first conductive line connected to the via, and changing a second width of a second conductive segment of the second conductive line connected to the via, so as to change impedances of the first conductive line and the second conductive line to match with a stub impedance of the via, reduce a parasite impedance of the via stub, reach an impedance match at a designed frequency point, and improve an integrity of a signal after traveling from the first conductive line, the via and the second conductive line.

The suppression method for reducing the via stub effect of the substrate of the present invention adopts a Smith Chart to adjust the first conductive line and the second conductive line to match the impedance with the via stub. Additionally, the aforementioned via can be through via and the substrate can be PCB or silicon substrate.

The present invention provides a suppression structure for reducing the via stub effect of the substrate. The suppression structure includes a first conductive line installed on the substrate, the first conductive line comprising a first conductive segment and a first remaining segment having a first remaining width different from a first width of the first conductive segment, the first conductive segment having one end connected to the first remaining segment; a via installed on the substrate and connected to the other end of the first conductive segment; and a second conductive line installed on the substrate, the second conductive line comprising a second conductive segment and a second remaining segment having a second remaining width different from a second width of the second conductive segment, the second conductive segment having one end connected to the second remaining segment, and the other end connected to the via.

The suppression method and structure for reducing the via stub effect of the substrate of the present invention increase the signal integrity during transmission by an impedance match method, which avoid the negative effect as parasite capacitance and resistance on the via open stub without adding any extra fabrication cost and affecting the wiring space on the substrate.

### BRIEF DESCRIPTION OF THE DRAWINGS

FIG. 1 is a schematic diagram showing the electrical connection of the signal conductive line and via or via stub;

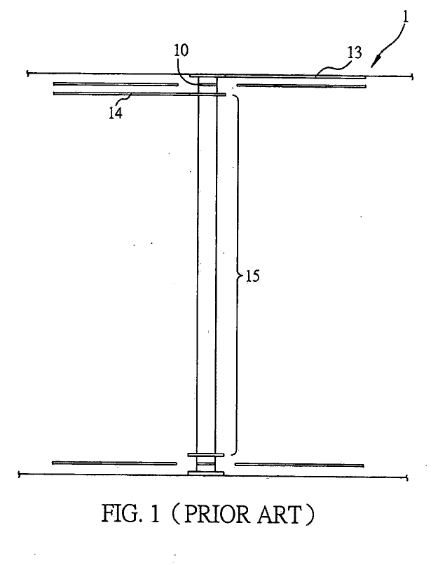

FIG. 2 is a schematic diagram showing the size change of the signal conductive line to match with the via's impedance;

FIG. 3 is the Smith Chart comparing the difference in reflection loss between the impedance mismatch and the impedance match of the signal conductive line and the via; and

FIG. 4 is a scattering parameter diagram comparing the difference in reflection loss and insertion loss between the impedance mismatch and the impedance match of the signal conductor and the via.

### DETAILED DESCRIPTION OF THE PERFERRED EMBODIMENTS

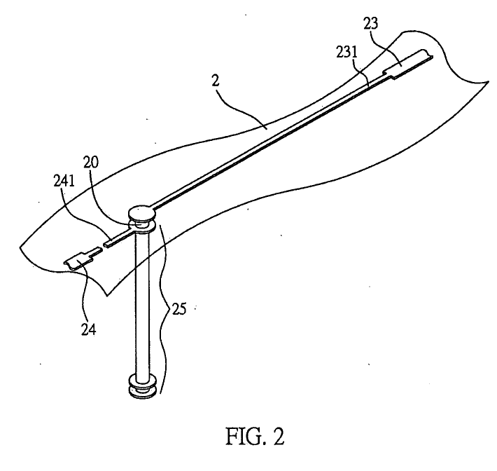

FIG. 2 illustrates an exemplary preferred embodiment of the present invention, which provides a suppression method for reducing the via stub effect of the substrate, applying on the substrate 2 which has via 20 and uses electrical connection to connect the first conductive line 23 and the second conductive line 24. The suppression method is to change widths of two conductive segments 231 and 241 of the first conductive line 23 and the second conductive line 24 connecting to the via 20, in order to change impedances of the conductive segments 231 and 241 of the first conductive line 23 and the second conductive line 24 to match with the via stub 25's impedance; thereby reducing the impedance discontinuity effect of the via stub 25 to reach the impedance match at the designed frequency point, results in increasing the signal integrity after signal is transmitted by the first conductive line 23, via 20 and the second conductive line 24.

The present invention of a suppression method for reducing the via stub effect of the substrate mentioned above, can use the Smith Chart to adjust the first conductive line and the second conductive line to match the impedance with the via stub. Additionally, the aforementioned via can be through via and the substrate can be PCB or silicon substrate.

The structure of the impedance match of this exemplary preferred embodiment is to change the widths at the location where the first conductive line 23 and the second conductive line 24 connect to the via 20, to change the impedances of the conductive segments of the first conductive line 23 and the second conductive line 24 to match with the via 20 or the via stub 25's impedance; thereby reducing the impedance discontinuity effect of the via 20 or the via stub 25 to reach the impedance match at the designed frequency point

As shown in FIG. 2, before taking the via stub 25's parasite impedance into account, the original design has an outer line width of 7 mils and an inner line width of 5 mils for the conductive line corresponding to the original designed impedance. However, after considering the parasite impedance of the via stub 25, an estimation calculated by impedance match determines that part of the lines 231 234, starting from the two terminal of the via to 250 mils distance far, have to reduce their line width from original 5 mils to 3 mils to achieve the impedance match of the designed frequency point 3 GHz.

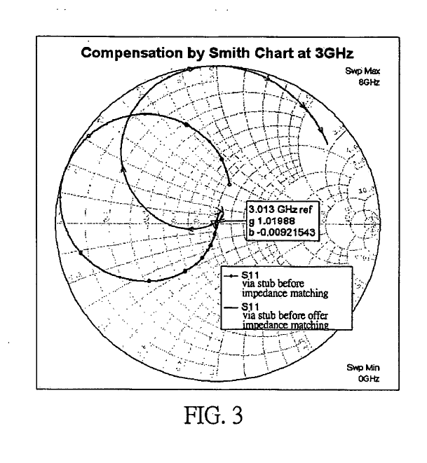

FIG. 3 is the Smith Chart, where it illustrates the difference in reflection loss between the impedance mismatch and the impedance match of the first conductive line 23, the second conductive line 24 and the via 20. As shown in the present exemplary preferred embodiment; when the impedance match point is set at 3 GHz, using the Smith Chart to adjust the impedance match of the first conductive line 23, the second conductive line 24 and the via that connects to the previous conductive lines by electrical connection, results in that the length and width of the part of line 231 241 should be 250 mils and 3.5 mils respectively.

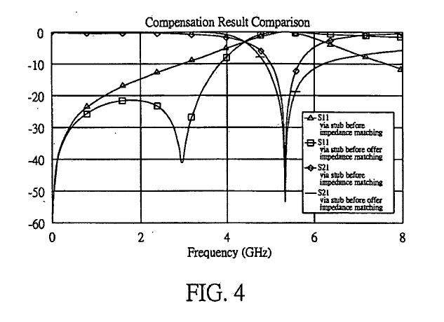

FIG. 4 is a scattering parameter diagram, which shows an obvious improvement of the S11 (reflection loss) and the S21 (insertion loss), after the first conductive line 23, the second conductive line 24, and the via stub 25 process the impedance match at the designed frequency point 3 GHz. Especially, for the reflection loss S11, where its value reduces 30 dB significantly after the impedance match comparing to the value before the impedance match. Thus, the results show that the method aforementioned here, at a specific frequency's signal transmission, for example 3 GHz, indeed improves the signal integrity effectively. Therefore, the prior art of the back drill is no longer used.

Comparing to the prior art, the present invention of the suppression method and structure for reducing the via stub effect of the substrate, increases the signal integrity during transmission by the impedance match method, which avoid the negative effects as parasite capacitance and resistance on the via open stub without adding any extra fabrication cost and affecting the wiring space on the substrate; therefore, resolves the drawbacks from the prior art respectively.

The invention has been described using an exemplary preferred embodiment above, however, it is to be understood that the scope of the present invention is not limited to the disclosed embodiments. On the contrary, it is intended to cover various modifications and similar changes. The scope of the claims, therefore, should be accorded the broadest interpretation so as to encompass all such modifications and similar arrangements.

What is claimed is:

1. A suppression method for suppressing a via stub effect of a substrate, the suppression method being applicable to a substrate having a via, a first conductive line and a second conductive line connected through the via to the first conductive line, the suppressing method comprising:
changing a first width of a first conductive segment of the first conductive line connected to the via, and changing a second width of a second conductive segment of the second conductive line connected to the via, so as to change impedances of the first conductive line and the second conductive line to match with a stub impedance of the via, reduce a parasite impedance of the via stub, reach an impedance match at a designed frequency point, and improve an integrity of a signal after traveling from the first conductive line, the via and the second conductive line.

2. The suppression method of claim 1, wherein both of the first width and the second width are changed in accordance with reflection losses of the first conductive lines and the second conductive line shown on a Smith Chart.

3. The suppression method of claim 1, wherein the via is a through via.

4. The suppression method of claim 1, wherein the substrate is a printed circuit board (PCB).

5. The suppression method of claim 1, wherein the substrate is a silicon substrate.

6. A suppression structure for suppressing a via stub effect of a substrate, the suppression structure comprising:
a first conductive line installed on the substrate, the first conductive line comprising a first conductive segment and a first remaining segment having a first remaining width different from a first width of the first conductive segment, the first conductive segment having one end connected to the first remaining segment;
a via installed on the substrate and connected to the other end of the first conductive segment; and
a second conductive line installed on the substrate, the second conductive line comprising a second conductive segment and a second remaining segment having a second remaining width different from a second width of the second conductive segment, the second conductive segment having one end connected to the second remaining segment, and the other end connected to the via.

7. The suppression structure of claim 6, wherein the via is a through via.

8. The suppression structure of claim 6, wherein the substrate is a PCB.

9. The suppression structure of claim 6, wherein the substrate is a silicon substrate.

10. The suppression structure of claim 6, wherein both of the first width and the second width are changed in accordance with reflection losses of the first conductive lines and the second conductive line shown on a Smith Chart.
